(19) United States
(12) Patent Application Publication
(10) Pub. No.: US 2013/0167368 A1
(43) Pub. Date: Jul. 4, 2013

(54) ASSEMBLY STRUCTURE

(71) Applicant: PEGATRON CORPORATION, Taipei City (TW)

(72) Inventors: Wei-Chih LAI, Taipei City (TW); Kuang-Jui CHENG, Taipei City (TW); Yung-Sheng LEE, Taipei City (TW); Chien-Feng MA, Taipei City (TW); Tien-Wen LIN, Taipei City (TW)

(73) Assignee: PEGATRON CORPORATION, Taipei City (TW)

(21) Appl. No.: 13/728,725

(22) Filed: Dec. 27, 2012

(30) Foreign Application Priority Data
Dec. 30, 2011 (TW) 100149966

(51) Int. Cl. H05K 13/00

(52) U.S. Cl. CPC H05K 13/00
USPC 29/729

(57) ABSTRACT

An assembly structure for carrying an electronic element and assisting in assembling or detaching the electronic element to or from a connector of an electronic device includes a base, a support and a hand-held element. The base disposed on the electronic device has a limiting part and an auxiliary part. The support used to carry the electronic element has an alignment part. When the support is mounted on the base, the alignment part is opposite to the limiting part, so that the alignment part is able to move within the limiting part. The hand-held element pivotally connected to the support has a hand-held part and a recess part. When the support is mounted on the base, the recess part is disposed across the auxiliary part. The support is moved with respect to the base, and two ends of the recess part contact against the auxiliary part.

### CROSS REFERENCE TO RELATED APPLICATIONS

This Non-provisional application claims priority under 35 U.S.C. §119(a) on Patent Application No(s). 100149966 filed in Taiwan, Republic of China on Dec. 30, 2011, the entire contents of which are hereby incorporated by reference.

### BACKGROUND

1. Technology Field

The disclosure relates to an assembly structure and, in particular, to an assembly structure used to carry an electronic element.

2. Related Art

With the progress of the technology, personal computers have gradually become indispensable home apparatuses. Recently, an all in one desktop or personal computer (hereinafter referred to as an all in one PC) has been developed in order to solve the conventional problems that the PC is very bulky accompanied by many externally added cables, and that the transportation of the PC is difficult. An integrated PC has a computer host integrated with a display as well as other peripherals, such as an optical disk device, a speaker and the like, in order to reduce the cables and the occupied space. In order to keep the light-and-handy property, the design of a casing of an integrated desktop computer is based on the slim-and-light principle. Correspondingly, the space inside the integrated PC is relatively restricted, so that the electronic elements inside the casing have to be arranged very densely.

In addition, in the typical integrated desktop computer, the hard disk drive or the optical disk device is typically mounted inside the computer casing by way of riveting or screwing. Because the hard disk drives and the optical disk devices have different external dimensions due to different brands or different models, the corresponding receptacles and securing mechanisms have to be designed according to the dimensions of the hard disk drives and the optical disk devices when the computers are assembled. Consequently, the difficulty and the assembling complexity are increased, and a lot of working time and manpower for assembling are wasted.

### SUMMARY

The disclosure is to provide an assembly structure capable of simplifying the method of attaching an electronic element, shortening the assembling time and assembling and detaching the electronic element easily within a limited space.

To achieve the above, an assembly structure of the present disclosure is used to carry an electronic element and to assist in assembling or detaching the electronic element with or from a connector of an electronic device. The assembly structure includes a base, a support, and a hand-held element. The base is disposed on the electronic device and has a limiting part and an auxiliary part. The support is used to carry the electronic element and has an alignment part. When the support is disposed on the base, the alignment part is opposite to the limiting part, so that the alignment part is able to move within the limiting part. The hand-held element is pivotally connected to the support and has a hand-held part and a recess part. When the support is disposed on the base, the recess part is disposed across the auxiliary part, the support is moved with respect to the base by rotating the hand-held element with respect to the support, and two ends of the recess part contact against the auxiliary part. Herein, when the support carrying the electronic element is moved in a direction to or away from the connector of the electronic device, the two ends of the recess part contact against the auxiliary part to assist in assembling or detaching the electronic element.

In one embodiment of the embodiment, the electronic element is an optical disk drive or a hard disk drive such as a 1.8″, 2.5″ or 3.5″ hard disc drive.

In one embodiment of the embodiment, the number of the alignment parts corresponds to the number of the limiting parts.

In one embodiment of the embodiment, the base has at least one opening disposed opposite the electronic device.

In one embodiment of the embodiment, the support has a support part, which carries the electronic element.

In one embodiment of the embodiment, the support has another support part, which carries another electronic element.

In one embodiment of the embodiment, the support has four fixing portions, which fix the electronic element.

In one embodiment of the embodiment, the hand-held element has a pivot shaft pivotally connected to the support.

As mentioned above, the assembly structure of the embodiment of the disclosure is used to carry the electronic element and to assist in assembling or detaching the electronic element with or from the connector of an electronic device. The assembly structure has the base, the support and the hand-held element. The alignment part of the support is opposite to the limiting part, and the recess part of the hand-held element is also opposite to the auxiliary part. When the support is assembled with the base, the alignment part can slide in the limiting part, and the recess part of the hand-held element can be disposed across the auxiliary part. By rotating the hand-held element, the support can be moved with respect to the base, and the alignment part is also movable within the limiting part, so that the disposed positions of the support and the base are fixed.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing an assembly structure and an electronic device of the disclosure;

FIGS. 2 and 3 are schematic decomposed illustrations showing an assembly structure according to a preferred embodiment of the disclosure;

FIG. 4 is a schematic assembled illustration showing the assembly structure of FIG. 2;

FIGS. 5A to 5C are schematic illustrations showing assembling of the assembly structure according to the preferred embodiment of the disclosure;

FIG. 5D is a schematic illustration showing the assembly structure according to the preferred embodiment of the disclosure; and

FIG. 6 is a schematic illustration showing an assembly structure according to another embodiment of the disclosure.

### DETAILED DESCRIPTION

The present invention will be apparent from the following detailed description, which proceeds with reference to the accompanying drawings, wherein the same references relate to the same elements.

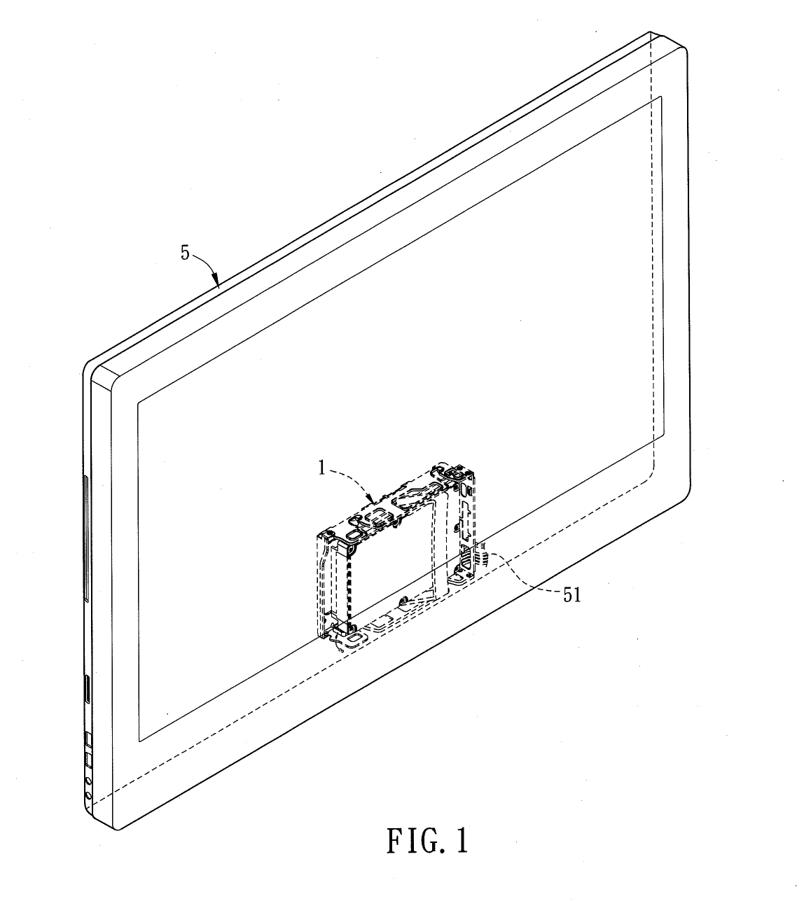

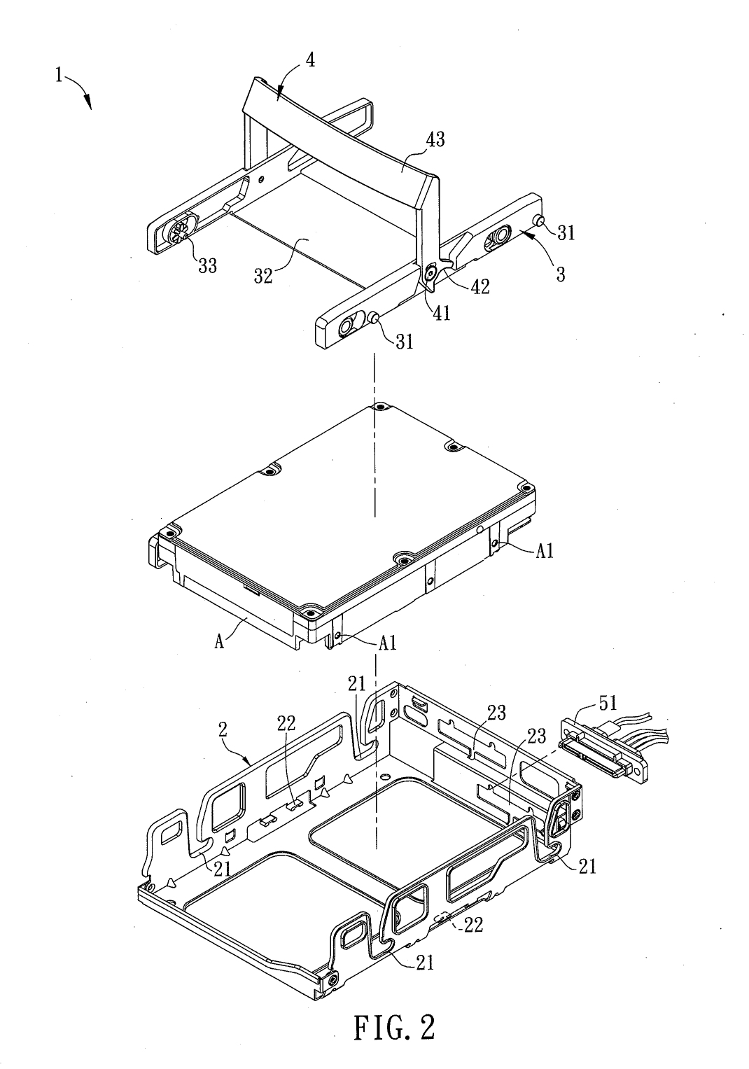

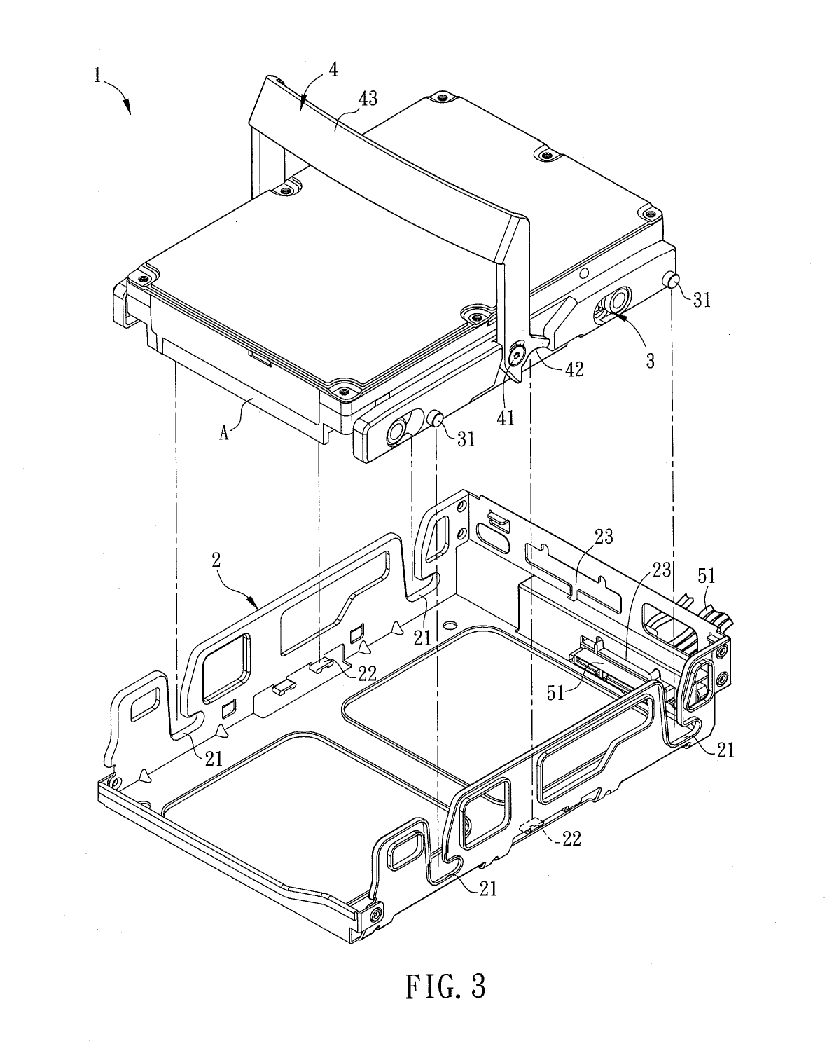

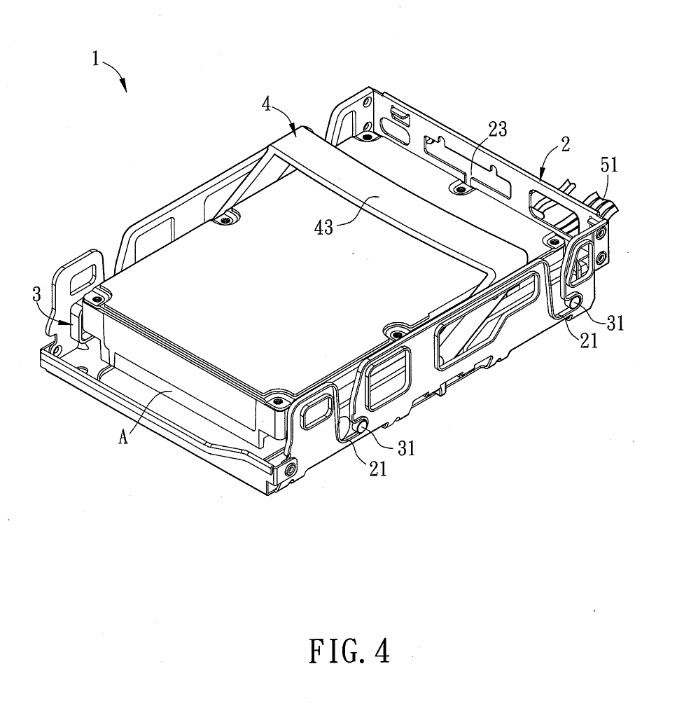

FIG. 1 is a schematic illustration showing an assembly structure and an electronic device of the disclosure, FIGS. 2 and 3 are schematic decomposed illustrations showing an assembly structure according to a preferred embodiment of the disclosure, and FIG. 4 is a schematic assembled illustration showing the assembly structure of FIG. 2. As shown in FIG. 1, an assembly structure 1 of the disclosure is disposed inside an electronic device 5. The electronic device 5 may be, for example, an all-in-one desktop computer (all-in-one desktop), a notebook computer, a typical desktop computer or any other electronic device. In this illustrative but non-limitative embodiment, the electronic device 5 is an all-in-one desktop computer. In order to illustrate and represent the architecture aspect of the assembly structure of the disclosure clearly, the electronic device is not shown in FIGS. 2 to 4.

The assembly structure 1 of the disclosure is used to carry an electronic element A and to assist in assembling or detaching the electronic element A with or from a connector 51 of the electronic device 5. The electronic element A is, for example, an optical disk device (ODD), a hard disc (HD) device or any other electronic element. The hard disc device may be, for example, a hard disk drive (HDD) or a solid state drive (SSD). In addition, the hard disc device may have the dimension of 1.8, 2.5 or 3.5 inches according to different specifications used. In the non-restrictive example of this embodiment, the assembly structure 1 carries a 3.5″ hard disc device. It is to be specified that the electronic element A may be connected to, for example, a mainboard, a power supply or the like through the connector 51. The assembly structure 1 includes a base 2, a support 3 and a hand-held element 4.

The base 2 is disposed on the electronic device 5, such as a housing of the electronic device 5. The base 2 has a limiting part 21 and an auxiliary part 22. In this embodiment, the limiting part 21 is, for example, a substantially L-shaped slot, and the auxiliary part 22 is, for example, a longitudinal plate-like part, and has two arced sides. In this example of this embodiment, the base 2 has four limiting parts 21 and four auxiliary parts 22, the limiting parts 21 are correspondingly disposed in a paired manner, and the auxiliary parts 22 are also correspondingly disposed in a paired manner. The numbers and positions of the limiting parts 21 and the auxiliary parts 22 do not intend to restrict the disclosure. In other embodiments, different numbers of limiting parts and auxiliary parts may be disposed on the base according to the different designs or sizes of the shaped patterns. For example, the base may have two auxiliary parts or six limiting parts.

In addition, the base 2 further has at least one opening 23 opposite to the electronic element A. For example, when the electronic element A is a hard disk drive and mounted on the base 2, the opening 23 is opposite to the cable connection portion of the hard disk drive, so that the hard disk drive can be connected to other elements through the opening 23 and the connector 51. The shape and size of the opening correspond to those of the electronic element A but do not intend to restrict the disclosure. In this example embodiment, the connector 51 is disposed in the opening 23.

The support 3 has an alignment part 31. When the support 3 is mounted on the base 2, the position of the alignment part 31 corresponds to that of the limiting part 21. In this illustrative but non-restrictive example of this embodiment, the alignment part 31 is a circular projection. In this embodiment, the size of the alignment part 31 is smaller than that of the limiting part 21. That is, the width of the alignment part 31 is smaller than the width of the limiting part 21, so that the alignment part 31 is movable within the limiting part 21. The support 3 further has a support part 32 and a fixing portion 33. The support part 32 carries and supports the electronic element A. The fixing portion 33 is fixed to the disposed position of the electronic element A. In this illustrative but non-restrictive example of this embodiment, the support 3 has four fixing portions 33. The fixing portions 33 are disposed on four corners of the support 3, respectively, and are opposite to a plurality of recesses A1 of the electronic element A, so that the fixing portion 33 of the support 3 can be fixed to the recess A1 of the electronic element A and the disposed positions of the support 3 and the electronic element A can be accordingly fixed.

In addition, the support 3 of the disclosure corresponds to the design of the carried electronic element A, such as the size of the support 3, the numbers of the support part(s) 32 and the fixing portion(s) 33 or the like. In another embodiment, if the assembly structure is used to carry two electronic elements, then the support may have two support parts for carrying the electronic elements, respectively.

The hand-held element 4 has a pivot shaft 41 pivotally connected to the support 3, so that the hand-held element 4 is rotatable relatively to the support 3. The hand-held element 4 has a recess part 42 and a hand-held part 43. When the support 3 is mounted on the base 2, the recess part 42 is disposed opposite the auxiliary part 22, so that the recess part 42 can be disposed across the auxiliary part 22. In this illustrative embodiment, the hand-held element 4 has two recess parts 42 disposed on two sides of the hand-held element 4, respectively. The recess parts 42 are disposed across one auxiliary part 22, so that the auxiliary part 22 can be disposed inside the recess part 42, and the two ends of the recess part 42 can contact against the auxiliary part 22. It is to be specified that when the support 3 of the electronic element A is carried to move in a direction to or away from the connector 51 of the electronic device 5, the two ends of the recess part 42 contact against the auxiliary part 22 in order to assist in assembling or detaching the electronic element A. The user can hold the hand-held part 43 to pick up the hand-held element 4 as well as the support 3 pivotally connected to the hand-held element 4. It is to be noted that the position of the auxiliary part 22 of the base 2 corresponds to the support 3 and the recess part 42 of the hand-held element 4. In this embodiment, the base 2 has four auxiliary parts 22, so the base 2 may work with more than two different sizes of supports 3 and hand-held elements 4.

Hereinabove, the assembly structure 1 disclosed by this disclosure has been discussed. In the following, the method of assembling the assembly structure 1 will be described in detail with reference to the actual application of the assembly structure 1 shown in FIGS. 2 to 4.

First, the electronic element A is disposed on the support part 32 of the support 3, as shown in FIG. 3, so that the support part 32 carries and supports the electronic element A. In addition, the fixing portion 33 of the support 3 is fixed to the recess A1 of the electronic element A, so that the disposed positions of the support 3 and the electronic element A are fixed. The user can hold the hand-held part 43 of the hand-held element 4 to pick up the support 3 carried with the electronic element A.

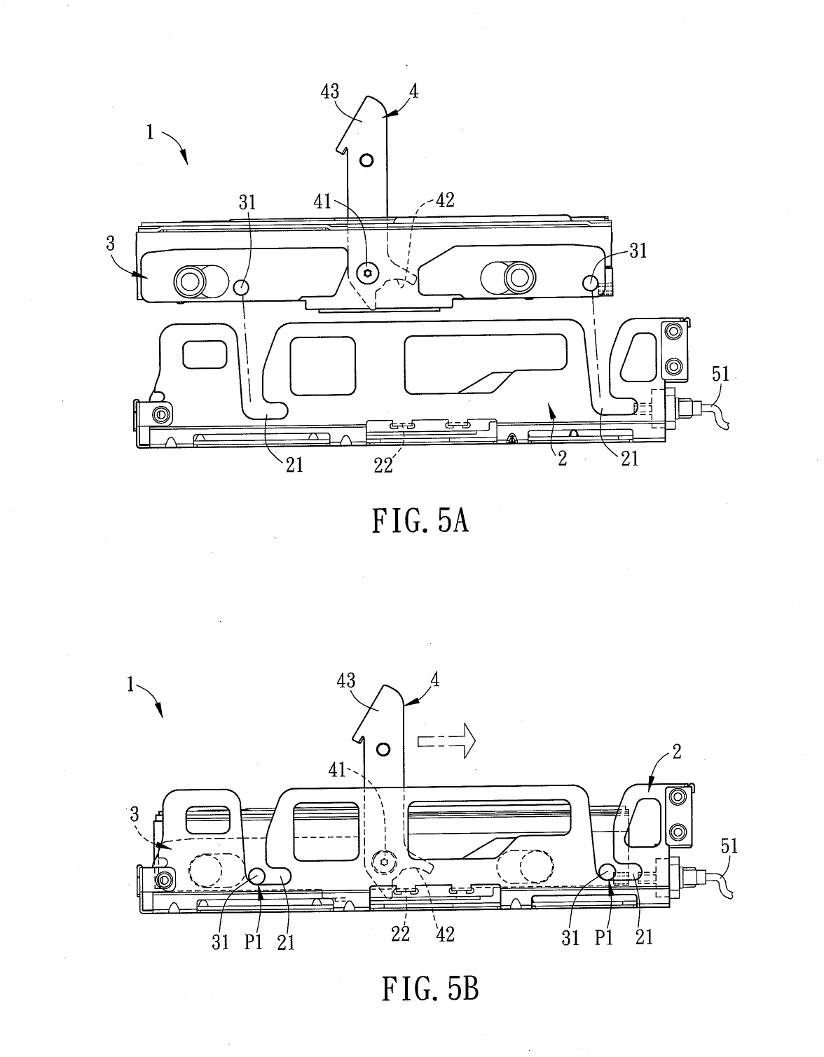

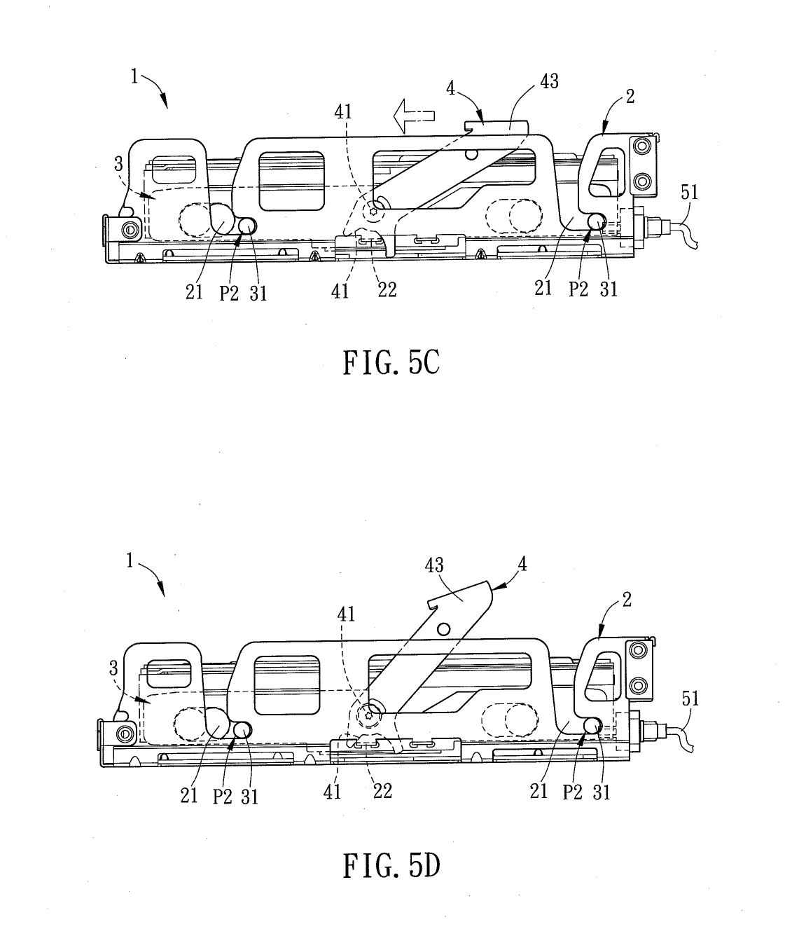

Next, the method of assembling the base 2 with the support 3 will be described with reference to FIGS. 5A to 5C, which are schematic illustrations showing assembling of the assembly structure according to the preferred embodiment of the disclosure. When the support 3 carried with the electronic element A is mounted on the base 2, the alignment part 31 of the support 3 is disposed opposite the limiting part 21, as shown in FIG. 5A, so that the alignment part 31 is movable within the limiting part 21 and the positioning effect can be achieved. Because the upper opening of the limiting part 21 is larger, the alignment part 31 can be easily placed in the limiting part 21. At this time, the hand-held element 4 is substantially perpendicular to the base 2 and the support 3.

When the alignment part 31 is placed on a bottom base of the limiting part 21, as shown in FIG. 5B, the recess part 42 of the hand-held element 4 is also disposed opposite the auxiliary part 22 of the base 2, so that the recess part 42 is disposed across the auxiliary part 22. In order to prevent the support 3, disposed on the base 2, from being moved in a vertical direction, the hand-held element 4 can be rotated rightwards, as shown in FIGS. 5B and 5C. Because the recess part 42 is disposed across the auxiliary part 22 and the hand-held element 4 is pressed down to make the front end of the recess part 42 rest against the auxiliary part 22, the support 3 is moved in the base 2, and the alignment part 31 is also moved in the limiting part 21 (e.g., moved from a first position P1 to a second position P2), so that the relative position between the support 3 and the base 2 is fixed. In addition, the electronic element A is further moved in a direction toward one side of the base 2 formed with the opening 23, so that the electronic element A can be connected to the connector 51 through the opening 23, and be connected to the element, such as a mainboard or a power supply, through the connector 51. Thus, if the connector 51 is firstly mounted in the opening 23 of the base 2, then the hand-held element 4 is rotated to move the support 3 and the electronic element A in the base 2 when the support 3 carried with the electronic element A is assembled with the base 2. Thus, the electronic element A can be moved in the direction toward one side of the base 2 formed with the opening 23, and can be directly connected to the connector 51 disposed in the opening 23.

FIG. 5D is a schematic illustration showing the assembly structure according to the preferred embodiment of the disclosure. As shown in FIG. 5D, when the support 3 is to be separated from the base 2, the hand-held element 4 can be rotated leftwards. Because the recess part 42 is disposed across the auxiliary part 22, and the hand-held element 4 is lifted up so that the rear end of the recess part 42 rests against the auxiliary part 22, the support 3 can be moved in the base 2, and the alignment part 31 is also moved in the limiting part 21 (e.g., moved from the second position P2 to the first position P1). Accordingly, the alignment part 31 is movable within the limiting part 21 and the support 3 can be separated from the base 2.

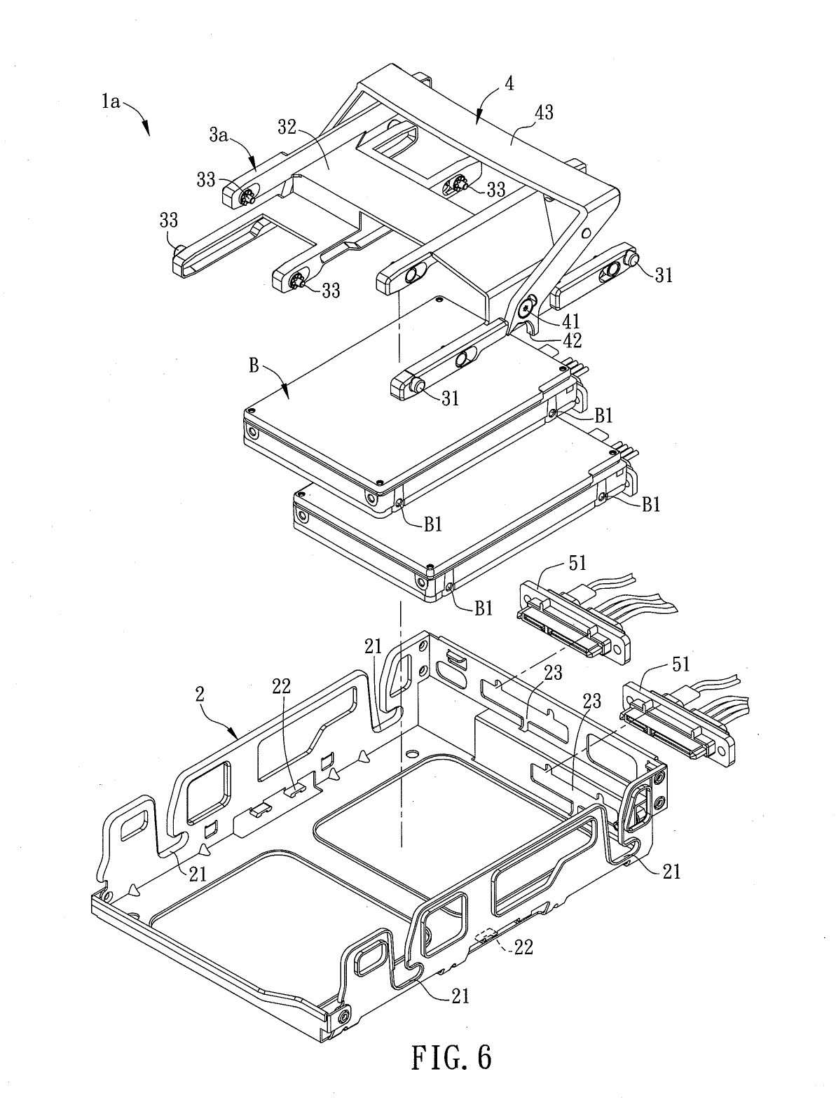

FIG. 6 is a schematic illustration showing an assembly structure according to another embodiment of the disclosure. As shown in FIG. 6, a assembly structure 1a of this embodiment differs from the assembly structure 1 of the above-mentioned embodiment in that the assembly structure 1a of this embodiment is used to carry two electronic elements B, each of which is a 2.5″ hard disk drive in this example.

In addition, a support 3a of this embodiment has a support part 32 and eight fixing portions 33. One electronic element B is disposed on the support part 32, and four fixing portions 33 are disposed in a plurality of recesses B1 of the electronic element B, respectively, so as to fix the position of the electronic element B. The other electronic element B is not disposed on the support part 32, and only four fixing portions 33 are provided to fix the position of the other electronic element B. The numbers and the positions of the support part(s) 32 and the fixing portions 33 of the support 3a in this embodiment do not intend to restrict the disclosure, and can be adjusted according to the application of the electronic element and the different numbers in different embodiments. When the support 3a carried with the electronic elements B is mounted on the base 2, the electronic elements B are disposed opposite a plurality of openings 23 of the base 2, respectively.

In summary, the assembly structure of the disclosure is used to carry the electronic element and to assist in assembling or detaching the electronic element with or from the connector of an electronic device. The assembly structure has the base, the support and the hand-held element. The alignment part of the support is opposite to the limiting part, and the recess part of the hand-held element is also opposite to the auxiliary part. When the support is assembled with the base, the alignment part can slide in the limiting part, and the recess part of the hand-held element can be disposed across the auxiliary part. By rotating the hand-held element, the support can be moved with respect to the base, and the alignment part is also movable within the limiting part, so that the disposed positions of the support and the base are fixed. In addition, when the support is moved in the base, the electronic element is further moved in the direction toward one side of the base formed with the opening, so that the electronic element can be connected to the connector through the opening, and can be connected to the element, such as the mainboard or the power supply, through the connector. Accordingly, the convenience in connection can be enhanced.

Compared with the conventional art, the electronic element can be attached to the assembly structure of the disclosure without riveting or screwing, so that the method of attaching the electronic element is simplified and the assembling time is shortened. In addition, the assembly structure can be used to carry different sizes of electronic elements so that the application range is broadened. Furthermore, the electronic element is assembled with the assembly structure of the disclosure in a vertical direction, so that the electronic element can be easily assembled and detached in the limited space.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An assembly structure used to carry an electronic element and to assist in assembling or detaching the electronic element with or from a connector of an electronic device, the assembly structure comprising:
a base, which is disposed on the electronic device and has a limiting part and an auxiliary part;
a support, which is used to carry the electronic element and has an alignment part, wherein when the support is disposed on the base, the alignment part is opposite to the limiting part, so that the alignment part is able to move within the limiting part; and
a hand-held element, which is pivotally connected to the support and has a hand-held part and a recess part, wherein when the support is disposed on the base, the recess part is disposed across the auxiliary part, the support is moved with respect to the base by rotating the hand-held element with respect to the support, and two ends of the recess part contact against the auxiliary part,
wherein when the support carrying the electronic element is moved in a direction to or away from the connector of the electronic device, the two ends of the recess part contact against the auxiliary part to assist in assembling or detaching the electronic element.

2. The assembly structure according to claim 1, wherein the electronic element is a hard disk drive or an optical disk drive.

3. The assembly structure according to claim 1, wherein the electronic element is a 1.8″ hard disc drive, a 2.5″ hard disc drive, or a 3.5″ hard disc drive.

4. The assembly structure according to claim 1, wherein the number of the alignment parts corresponds to the number of the limiting parts.

5. The assembly structure according to claim 1, wherein the base has at least one opening disposed opposite the electronic device.

6. The assembly structure according to claim 1, wherein the support has a support part, which carries the electronic element.

7. The assembly structure according to claim 6, wherein the support has another support part, which carries another electronic element.

8. The assembly structure according to claim 1, wherein the support has four fixing portions, which fix the electronic element.

9. The assembly structure according to claim 1, wherein the hand-held element has a pivot shaft pivotally connected to the support.
